(19) United States
(12) Patent Application Publication
(10) Pub. No.: US 2021/0126140 A1
(43) Pub. Date: Apr. 29, 2021

(54) SURFACE MOUNT SOLAR CELL HAVING LOW STRESS PASSIVATION LAYERS

(71) Applicant: Array Photonics, Inc., Tempe, AZ (US)

(72) Inventors: Lan ZHANG, Palo Alto, CA (US); Ewelina LUCOW, Los Gatos, CA (US); Ligang GAO, Mesa, AZ (US)

(73) Assignees: Array Photonics, Inc., Tempe, AZ (US); Array Photonics, Inc., Tempe, AZ (US)

(21) Appl. No.: 16/963,193

(22) PCT Filed: Jan. 17, 2019
(86) PCT No.: PCT/US2019/013943

§ 371 Date: Jul. 17, 2020

Related U.S. Application Data
(60) Provisional application No. 62/619,435, filed on Jan. 19, 2018.

(51) Int. Cl. H01L 31/0224; H01L 31/0687; H01L 31/05; H01L 31/18

(52) U.S. Cl. CPC H01L 31/02245; H01L 31/1868; H01L 31/05; H01L 31/0687

(57) ABSTRACT

Surface mount semiconductor devices and methods for fabricating surface mount semiconductor devices are disclosed. In particular, back-contact-only multijunction photovoltaic cells and the process flows for making such cells are disclosed. The surface mount multijunction photovoltaic cells include through-wafer-vias for interconnecting the front surface epitaxial layer to a contact pad on the back surface. Before etching the through-wafer-vias the substrate is thinned to less than 150 μm. The through-wafer-vias are formed using a wet etch process that removes semiconductor materials non-selectively without major differences in etch rates between heteroepitaxial III-V semiconductor layers. Low stress passivation layers are used to reduce the thermo-mechanical stress of the semiconductor devices.

This application claims the benefit under 35 U.S.C. § 119(e) of U.S. Provisional Application No. 62/619,435, filed on Jan. 19, 2018, which is incorporated by reference in its entirety.

### FIELD

This disclosure relates to photovoltaic cells, methods for fabricating photovoltaic cells, methods for assembling solar panels, and solar panels comprising photovoltaic cells. Particularly, the disclosure relates to surface mount multijunction photovoltaic cells. The surface mount multijunction photovoltaic cells include through-wafer-vias for interconnecting a front surface epitaxial layer to a contact pad on the back surface. The through-wafer-vias are formed using a wet etch process that removes semiconductor materials non-selectively without major differences in etch rates between heteroepitaxial III-V semiconductor layers. Low stress passivation layers are used to improve reliability of the devices over a broad temperature range.

### BACKGROUND

Multijunction photovoltaic cells are used in terrestrial and space solar conversion applications because of their high efficiencies. Such cells have multiple junctions, or sub-cells, that form diodes and are connected in series. The structures are realized through epitaxial growth of multiple layers on semiconductor substrates. Each subcell in a stack possesses a unique bandgap and is optimized for absorbing a different portion of the solar spectrum, thereby improving efficiency of solar energy conversion. These subcells are chosen from a variety of semiconductor materials with different optical, electrical, and physical properties in order to absorb different portions of the solar spectrum. The materials are arranged such that the bandgap of the subcells is progressively smaller from the top subcell (closest to the front surface, from which the cell receives light) to the bottom subcell (furthest from the front surface). Thus, high-energy photons are absorbed in the top subcell and less energetic photons pass through to the lower subcells where they are absorbed. In every subcell, electron-hole pairs are generated and current is collected at ohmic contacts in the solar cell. Semiconductor materials used to form the subcells include, for example, germanium and alloys of one or more elements from group III and group V on the periodic table. Examples of these alloys include, for example, indium gallium phosphide, indium phosphide, gallium arsenide, aluminum gallium arsenide, indium gallium arsenide, and dilute nitride compounds. For ternary and quaternary compound semiconductors, a wide range of alloy ratios can be used. Examples of multijunction solar cells using multiple heteroepitaxial layers are described in U.S. Pat. Nos. 8,575,473, 8,697,481 and 9,214,580.

Using conventional photovoltaic cells, solar arrays used to power space satellites are typically assembled manually which results in high cost and introduces the risk of reliability issues. Nearly all currently available space photovoltaic cells employ welded interconnect tabs for adjacent cells, and a welded or monolithically integrated bypass diode on each individual photovoltaic cell. Photovoltaic cells assembled with bypass diodes, interconnects, and coverglass are referred to in the aerospace industry as “Coverglass Interconnected Cells” or “CICs”. These CICs are typically assembled using manual process steps. The mechanical design of commercially available CICs has not changed substantially in the past two decades.

To reduce the number of overall steps associated with the expensive, manual process steps used in both CIC and solar array assembly, the industry has been moving to increasingly larger CICs using both 4-inch and 6-inch Ge substrates.

Normally, a photovoltaic cell contributes around 20% to the total cost of a photovoltaic power module. Higher photovoltaic cell efficiency means more cost-effective modules. Fewer photovoltaic devices are then needed to generate the same amount of output power, and the generation of higher power with fewer devices leads to reduced system costs, such as costs associated with structural hardware, assembly processes, wiring for electrical connections, etc. In addition, by using high efficiency photovoltaic cells to generate the same power, less surface area, fewer support structures, and lower labor costs are required for assembly installation.

Photovoltaic modules are a significant component in spacecraft power systems. Lighter weight and smaller photovoltaic modules are always preferred because the lifting cost to launch satellites into orbit is very expensive. Efficient surface area utilization of photovoltaic cells is especially important for space power applications to reduce the mass and fuel penalty associated with large photovoltaic arrays. Higher specific power (watts generated over photovoltaic array mass), which reflects the power one solar array can generate for a given launch mass, can be achieved with more efficient photovoltaic cells because the size and weight of the photovoltaic array will be less for the same power output. Additionally, higher specific power can be achieved using smaller cells that are more densely arranged over a photovoltaic array of a given size and shape.

Interconnection of multijunction photovoltaic cells is typically accomplished by welding interconnect ribbons to front side and back side contacts on the p- and n-sides of the device. Interconnecting multijunction photovoltaic cells using these methods can be costly. To minimize interconnection costs, it can be desirable to use larger area photovoltaic cells to reduce the number of interconnects that need to be formed for a given panel area. This can lead to a reduction in surface area utilization. Interconnect welding is usually the most delicate operation in CIC assembly.

More recently, solar cells employing via structures have been proposed to facilitate electrical connections on one side of the wafer. Conventional solar cell designs require metallization to form top-surface electrodes, which are usually regular grids of metal fingers or wires. These structures result in shadowing loss, since the metal gridlines prevent light from being absorbed under them. This can reduce the active area of the solar cells. Through wafer vias (TWVs) are electrical interconnects between the top (front) and bottom (back) surfaces of a device. TWVs are widely used in microelectronics applications and have been proposed for solar cells to reduce shadowing losses as well as to facilitate subsequent packaging. An example of this approach is known as the surface mount coverglass cell (SMCC). Examples of SMCC devices, and associated processing of TWVs are described in U.S. Pat. No. 9,680,035, and U.S. Application Publication No. 2017/0213922, each of which is incorporated by reference in their entirety. SMCCs are photovoltaic cells with TWVs, all-backside surface mount contacts and coverglass integrated at the wafer-level. With all the electrical contacts on the backside of the photovoltaic cell, individual photovoltaic cells can be assembled onto printed wiring boards (PWBs), printed circuit boards (PCBs) or other interconnection substrates to provide a solar array using standard electronics industry pick-and-place assembly equipment and practices. SMCC multijunction photovoltaic cells (SMCC) can be surface mounted to a variety of substrates using well-known, low cost, high throughput, surface mount methods used throughout the semiconductor industry.

Solar arrays for satellites must be efficient, are expected to operate over a broad temperature range, and must be capable of withstanding many thermal cycles during the operational lifetime. The expected temperature range for operation may vary in a range between about −200° C. and +150° C. Furthermore, packaging may require high temperature process steps, for example, to form solder bumps that connect the solar cells with PCBs. Consequently, thermal expansion and contraction can lead to failure of components, for example, through cracking, peeling and spalling. A large mismatch of the coefficient of thermal expansion between semiconductor materials, dielectrics, and metal layers that are in close proximity can cause a large stress to develop. These stresses can lead to reliability issues, for example, cracking and/or interfacial delamination that affects electrical connectivity.

Multijunction solar cell structures and devices with improved thermo-mechanical properties are therefore required to reduce the cyclic mechanical stress experienced by a device, and to produce a more reliable device.

### SUMMARY

According to the present invention, through-wafer via structures, comprise: a substrate having a front substrate surface and a back substrate surface, wherein the substrate has a thickness from 20 μm to 200 μm; a plurality of heteroepitaxial layers overlying the front substrate surface; a front surface contact overlying a portion of and electrically connected to the plurality of heteroepitaxial layers; an optical adhesive overlying the front surface contact and the plurality of heteroepitaxial layers; a coverglass overlying the optical adhesive; a back surface solder pad underlying a portion of and electrically connected to the back substrate surface; a front surface solder pad underlying and insulated from the back substrate surface; and a through-wafer-via interconnecting the front surface solder pad and the front surface contact, wherein the through-wafer via comprises a sidewall and a low stress passivation layer lining the sidewall.

According to the present invention, semiconductor devices comprise the through-wafer via structure according to the present invention.

According to the present invention, multijunction photovoltaic cell comprising the through-wafer via structure according to the present invention.

According to the present invention, photovoltaic modules comprise a plurality of the multijunction photovoltaic cells according to the present invention.

According to the present invention, power systems comprise the photovoltaic module according to the present invention.

According to the present invention, methods of fabricating a through-wafer via structure, comprise (a) providing a semiconductor wafer, wherein the semiconductor wafer comprises: a substrate comprising a front substrate surface and a back substrate surface; a plurality of heteroepitaxial layers overlying the front substrate surface; a front surface contact overlying and electrically connected to a portion of the plurality of heteroepitaxial layers; an optical adhesive overlying the front surface contact and the plurality of heteroepitaxial layers; and a coverglass overlying the optical adhesive layer; (b) thinning the substrate to a thickness from 20 μm to 150 μm; (c) forming a through-wafer via interconnecting the front surface contact, wherein the through-wafer-via comprises a sidewall and a low stress passivation layer lining the sidewall; and (d) forming a front contact pad interconnecting the through-wafer via and to the front surface contact.

### BRIEF DESCRIPTION OF THE DRAWINGS

The drawings described herein are for illustration purposes only. The drawings are not intended to limit the scope of the present disclosure.

FIG. 1 shows a cross-sectional view of an example of a multijunction photovoltaic cell.

FIG. 2 shows a cross-sectional view of an example of a surface mount multijunction photovoltaic cell according to the present disclosure.

FIG. 3 shows a bottom view of an example of a surface mount multijunction photovoltaic cell according to the present disclosure.

FIG. 4 shows a cross-sectional view of an example of a surface mount coverglass cell (SMCC) according to the present disclosure.

FIGS. 5-14 illustrate an example of a process flow for fabricating a multijunction photovoltaic cell having TWVs according to the present disclosure.

FIG. 15 shows a cross-sectional view of a multijunction photovoltaic cell with a TWV fabricated using the method illustrated in FIGS. 5-14.

FIG. 16A shows a top view of the multijunction photovoltaic cell shown in FIG. 15.

FIG. 16B shows a bottom view of the multijunction photovoltaic cell shown in FIG. 15.

FIG. 17A and FIG. 17B show cross-sectional views of a dielectric passivation layer deposited onto a TWV sidewall.

FIG. 18 is a photograph showing cracks on a wafer having an overlying dielectric passivation layer.

FIG. 19 shows a cross-sectional view of a TWV with a delaminated photoresist passivation layer.

FIG. 20A and FIG. 20B show cross-sectional views of TWVs with a photoresist passivation layer, with metal cracking.

FIG. 21 shows a cross-sectional view of a polyimide passivation layer on a TWV sidewall.

### DETAILED DESCRIPTION

The following detailed description refers to the accompanying drawings that show, by way of illustration, specific details and embodiments in which the invention may be practiced. These embodiments are described in sufficient detail to enable those skilled in the art to practice the present invention. Other embodiments may be utilized, and structural, logical, and electrical changes may be made without departing from the scope of the invention. The various embodiments disclosed herein are not necessarily mutually exclusive, as some disclosed embodiments may be combined with one or more other disclosed embodiments to form new embodiments. The following detailed description is, therefore, not to be taken in a limiting sense, and the scope of the embodiments of the present invention is defined only by the appended claims, along with the full scope of equivalents to which such claims are entitled.

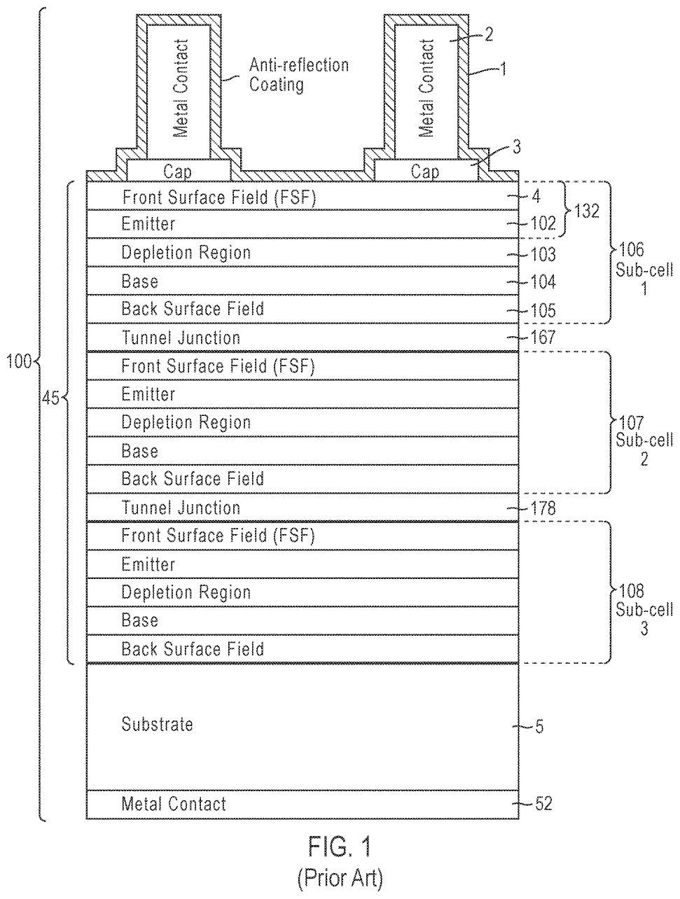

Conventional multijunction solar cells have been widely used for terrestrial and space applications because of their high conversion efficiency. Multijunction solar cells (100), as shown in FIG. 1, include multiple diodes in series connection, known in the art as junctions or subcells (106, 107, and 108), realized by growing thin regions of epitaxy in a stack on a semiconductor substrate. Each subcell in a stack possesses a unique bandgap and is optimized for absorbing a different portion of the solar spectrum, thereby improving efficiency of solar energy conversion. These subcells are chosen from a variety of semiconductor materials with different optical and electrical properties that absorb different portions of the solar spectrum. The materials are arranged such that the bandgap of the subcells becomes progressively narrower from the top subcell (106) to the bottom subcell (108). Thus, high-energy photons are absorbed in the top subcell and less energetic photons pass through to the lower subcells where they are absorbed. In every subcell, electron-hole pairs are generated and current is collected at ohmic contacts in the solar cell. Semiconductor materials used to form the subcells include, for example, germanium and alloys of one or more elements from group III and group V on the periodic table. Examples of these alloys include, for example, indium gallium phosphide, indium phosphide, gallium arsenide, aluminum gallium arsenide, indium gallium arsenide, and dilute nitride compounds. For ternary, quaternary, and quinary compound semiconductors, a wide range of alloy ratios can be used.

As shown in FIG. 1, a multijunction solar cell 100 can include a substrate 5, a back metal contact 52 underlying and electrically connected to the substrate 5, a subcell 108 overlying the substrate, a subcell 107 overlying the subcell 108, and a subcell 106 overlying the subcell 107. A cap region 3 overlies and is electrically connected to a portion of subcell 6 and a metal contact 2 overlies and is electrically connected to each of the cap regions 3. An antireflection coating 1 overlies a portion of subcell 6, cap regions 3, and metal contacts 2. Heteroepitaxial region 45 includes subcells 106, 107, and 108, and each subcell is interconnected to the adjacent subcell by a tunnel junction 167 and 178. Each subcell includes multiple heteroepitaxial layers. For example, subcell 106 includes front surface field 4, emitter 102, depletion region 103, base 104, and back surface field 105. Front surface field 4 and emitter 102 form element 132.

The fabrication of surface mount coverglass cell (SMCC) multijunction photovoltaic cells includes forming high quality through-wafer vias (TWVs) across the complex heteroepitaxial structure.

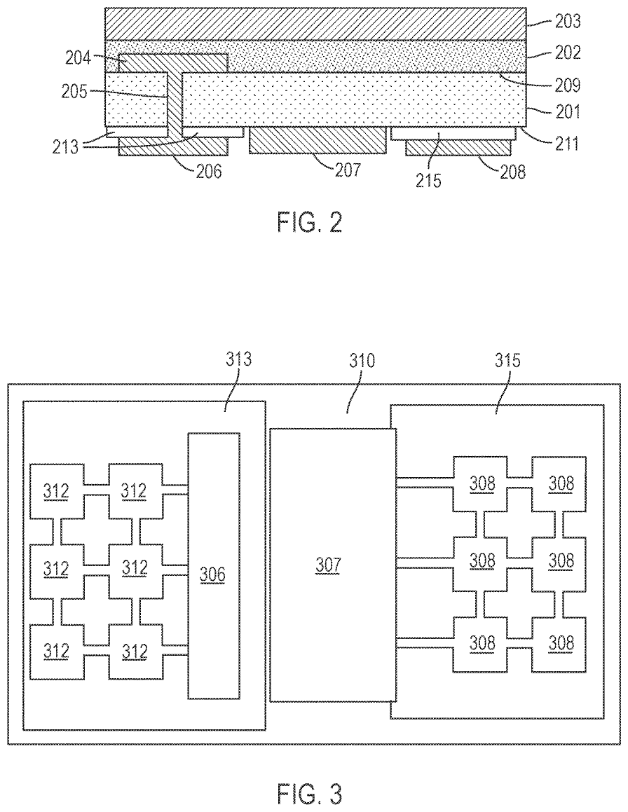

FIG. 2 shows a cross-sectional view of an example of a SMCC device provided by the present disclosure. The SMCC shown in FIG. 2 includes semiconductor layer 201, which includes multiple heteroepitaxial layers overlying substrate, and a coverglass 203, bonded to the front surface 209 of the semiconductor layer 201 using an optical adhesive 209. Front surface contact 204 on the front surface 209 of semiconductor layer 201 is interconnected to front surface pad 206 by through-wafer via (TWV) 205. Front surface pad 206 and TWV 205 are electrically insulated (not shown) from semiconductor layer 201. Front surface pad 206 is isolated from semiconductor layer 201 by passivation layer 213. Back surface 211 of semiconductor layer 201 is interconnected to back surface contact 207. Back surface solder pad 208 is disposed on and electrically insulated from back surface 211 of semiconductor layer 201 by passivation layer 215 and is electrically interconnected (not shown) to back surface contact 207.

When referring to the various surfaces of a multijunction solar cell, the front surface or top surface refers to the surface designed to face incident solar radiation, and the back surface or bottom surface refers to the side of the solar cell facing away from the incident solar radiation.

FIG. 3 shows a back surface view of the SMCC device shown in FIG. 2.

Front surface pad 306 is interconnected to the front surface contact (not shown). Front surface pad 306 is interconnected to front surface solder pads 312 for interconnecting the SMCC device to a printed circuit board or to other interconnection substrates. The front surface pad 306 and front surface solder pads 312 are isolated from the semiconductor layer 310 by passivation layer 313, which covers a portion of semiconductor layer 310. Back surface contact 307 is disposed on the back surface of the SMCC device and is interconnected to back surface mount solder pads 308 for interconnecting the SMCC device to a printed circuit board. Back surface contact 307 is electrically connected to semiconductor layer 310. Back surface solder pads 308 are electrically isolated from semiconductor layer 310 by passivation layer 315.

The coverglass 203 (FIG. 2) can be any suitable optically transparent dielectric material appropriate for use in solar cells. The coverglass can be a sheet of material. The coverglass can be any suitable thickness for protecting the solar cell from the environment and radiation. For example, the coverglass can be from 20 μm to 600 μm thick, from 40 μm to 500 μm thick, from 50 μm to 400 μm thick, or from 75 μm to 300 μm thick.

The optical adhesive 202 (FIG. 2) can be any suitable optical adhesive capable of bonding the coverglass to underlying layers including to a heteroepitaxial layer, to an antireflection coating (ARC), and/or to metal contact layers. An example of a suitable optical adhesive is Dow Corning® 93-500 space grade encapsulant. An optical adhesive can be, for example, from 2 μm to 200 μm thick, from 5 μm to 150 μm thick, or from 10 μm to 100 μm thick.

Front surface contact 204 (FIG. 2) can comprise one or more layers and can be, for example, less than 0.2 μm thick, less than 10 μm thick, less than 20 μm thick, or less than 40 μm thick. Thicker front surface metal pads can comprise multiple layers such as, for example, layers of Au, Ag, Ti, Ni, Cr, or combinations of any of the foregoing. Each layer can be, for example, from 1 μm to 10 μm thick, or from 0.1 μm to 1 μm thick. Front surface metal pad 204 is electrically connected to front surface 209 of semiconductor 201 such as to the top surface of the heteroepitaxial layer.

Heteroepitaxial region 201 (FIG. 2) can comprise multiple heteroepitaxial layers which are deposited or grown on a substrate. Semiconductor layer 201 comprises the active multijunction photovoltaic cell. The multijunction photovoltaic cell can comprise one or more subcells. Examples of multijunction photovoltaic cells are disclosed in U.S. Pat. No. 8,912,433, in U.S. Pat. No. 8,962,993, in U.S. Pat. No. 9, 214,580, in U.S. Application Publication No. 2017/0110613, and in U.S. application Ser. No. 15/609,760 filed on May 31, 2017, each of which is incorporated by reference in its entirety. The heteroepitaxial layer can include multiple layers of semiconductor material used to fabricate a multijunction photovoltaic cell such as shown in FIG. 1. In certain multijunction photovoltaic cells, at least one of the junctions can comprise a dilute nitride material such as GaInNAsSb, GaInNAsBi, or GaInNAsSbBi. Each of the subcells can be lattice matched to each of the other subcells forming the multijunction photovoltaic cell and can be lattice matched to the substrate.

“Lattice matched” refers to semiconductor layers for which the in-plane lattice constants of adjoining materials in their fully relaxed states differ by less than 0.6% when the materials are present in thicknesses greater than 100 nm. Further, subcells that are substantially lattice matched to each other means that all materials in the subcells that are present in thicknesses greater than 100 nm have in-plane lattice constants in their fully relaxed states that differ by less than 0.6%. In an alternative meaning, substantially lattice matched refers to the strain. As such, base layers can have a strain from 0.1% to 6%, from 0.1% to 5%, from 0.1% to 4%, from 0.1 to 3%, from 0.1% to 2%, or from 0.1% to 1%; or can have strain less than 6%, less than 5%, less than 4%, less than 3%, less than 2%, or less than 1%. Strain refers to compressive strain and/or to tensile strain.

A substrate included in the semiconductor layer can be active and can form one of the active junctions of the photovoltaic cell, or the substrate can be inactive. An example of an active substrate is Ge. A Ge substrate can be less than 200 μm thick, less than 175 μm thick, less than 150 μm thick, or less than 100 μm thick. A Ge substrate can be, for example, from 20 μm to 200 μm thick, from 20 μm to 175 μm thick, from 20 μm to 150 μm thick, from 50 μm to 175 μm thick, from 50 μm to 150 μm, or from 50 μm to 80 μm thick. An example of an inactive substrate is GaAs, which can be, for example, from 10 μm to 400 μm thick, from 20 μm to 200 μm thick, from 20 μm to 150 μm thick, from 50 μm to 150 μm thick, from 40 μm to 90 μm thick, from 50 μm to 80 μm thick, or from 50 μm to 70 μm thick.

Front surface contact 206 (FIG. 2) and 306 (FIG. 3) can include one or more layers of electrically conductive metals such as Au, Ag, Ti, Ni, Cr, or a combination of any of the foregoing. The front surface contact 206 and 306 can be, for example, less than 0.2 μm thick, less than 0.5 μm thick, or less than 1 μm thick, and each of the electrically conductive layers can be, for example, from 0.1 μm to 1 μm thick, from 1 μm to 20 μm thick, or from 1 μm to 10 μm thick.

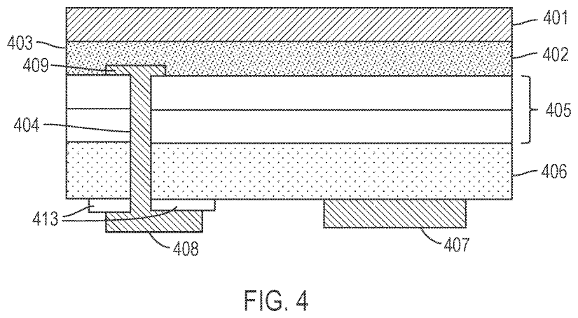

FIG. 4 shows a cross-section view of an example of a surface mount coverglass cell (SMCC) provided by the present disclosure. The SMCC device includes coverglass 401 bonded to the front surface of heteroepitaxial layer 405 with optical adhesive 402. Heteroepitaxial layer 405 includes two subcells and overlies substrate 406. Substrate 406 can be a thinned substrate, having, for example, a thickness less than 150 μm. Front surface contact 409 is interconnected to the front surface of heteroepitaxial layers 405. Front surface contact 409 is interconnected to front surface pad 408 on the back side of the device by TWV 404. Front surface pad 408 is electrically isolated from substrate 406 by passivation layer 413. TWV 404, front surface contact 409 and front surface pad 408 are electrically isolated from heteroepitaxial layer 405 and substrate 406. Back surface contact 407 underlies and is interconnected to substrate 406. It can be appreciated that many details of a SMCC are not shown in FIG. 4.

The SMCC devices can be mounted to an interconnection substrate such as a PWB or a PCB using any suitable surface mount assembly method and using any suitable surface mount assembly materials.

An interconnection substrate such as PWB or PCB can be made of any suitable material, which can depend on the application. For example, for space applications, the printed circuit board will be qualified for space applications. A PWB or PCB can comprise solder pads for surface mounting the SMCCs and interconnects for connecting each of the SMCC devices. Bypass diodes can be mounted on the printed circuit board such as on the side of the printed circuit board opposite the side on which the SMCC devices are mounted. A bypass diode may be interconnected to one or more SMCC devices.

The front surface of the epitaxial layer can comprise front surface contacts in the form of thin lines forming a grid. The grid can be interconnected to a busbar. TWVs can interconnect the busbar to front surface contact pads located on the back side of the SMCC.

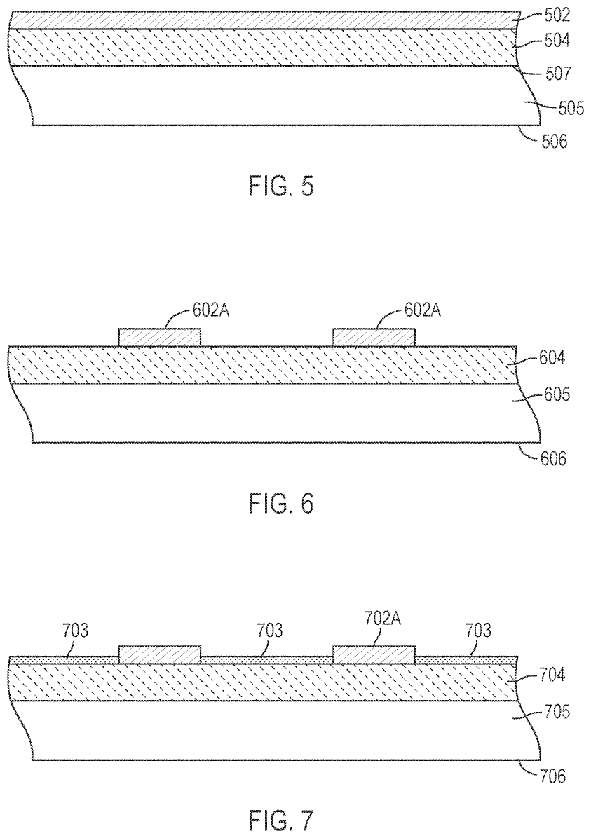

FIGS. 5 to 15 illustrate an example of process steps used to fabricate a SMCC provided by the present disclosure. FIGS. 5 to 8 show steps associated with front-side processing. FIGS. 9 to 15 show steps associated with back-side processing including deposition of a low-stress passivation layer provided by the present disclosure. The process steps and final product described can be modified by one skilled in the art to accommodate a wide variety of semiconductor devices; the steps and final product are not limited to solar cells and are applicable to other semiconductor devices and in particular to minority carrier devices.

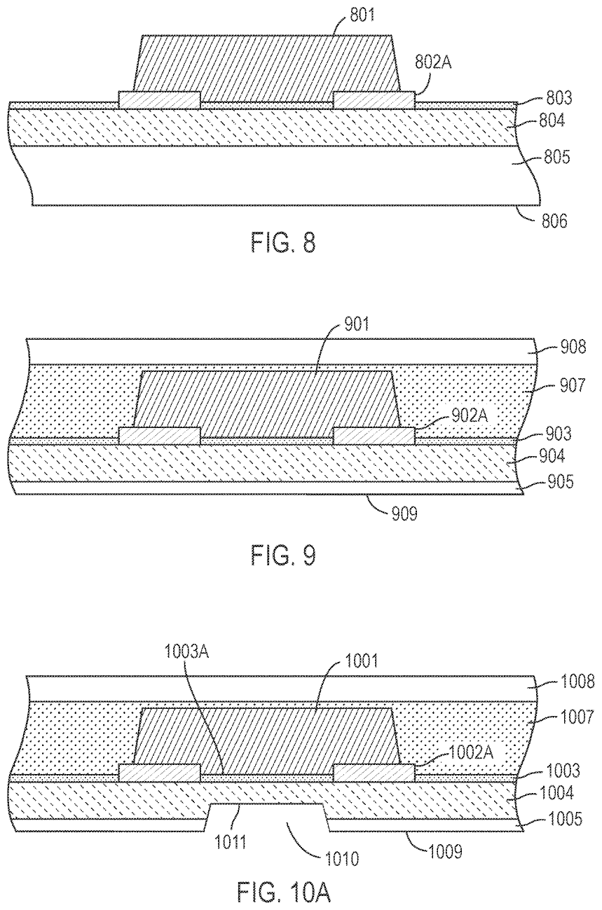

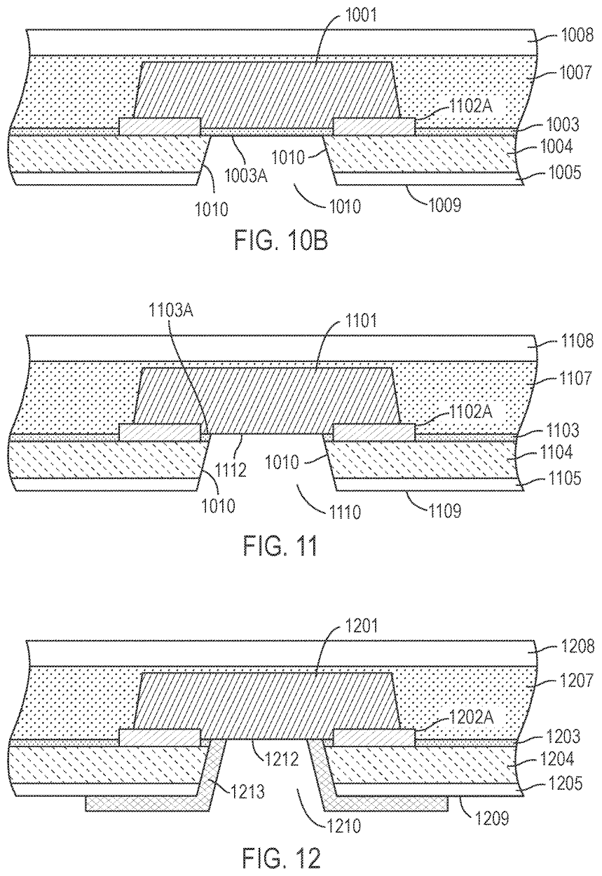

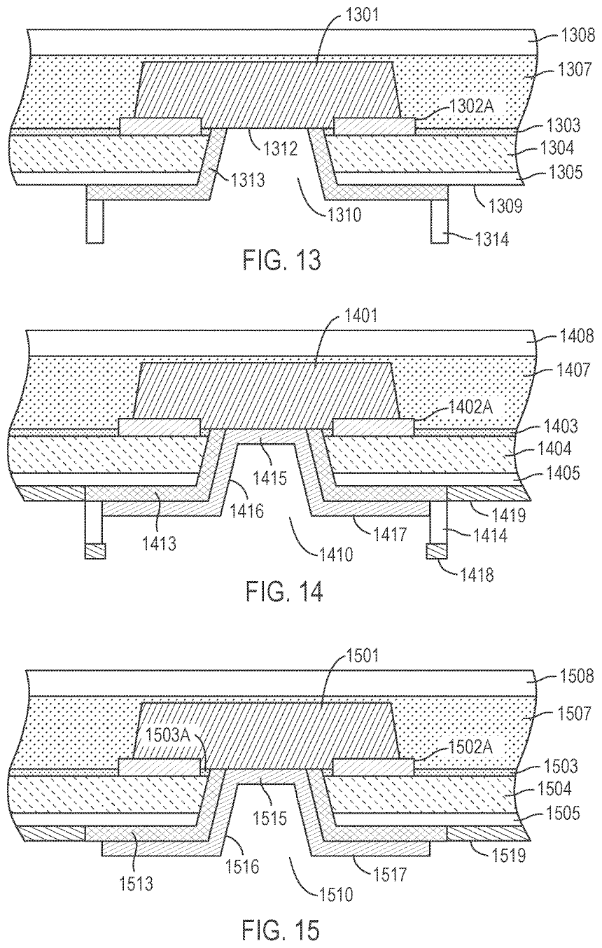

The semiconductor wafer cross-sections shown in FIGS. 5 to 15 can be summarized as follows: FIG. 5 shows a heteroepitaxial layer on an unmodified substrate; FIG. 6 shows a wafer after contact cap layer patterning; FIG. 7 shows a wafer following application of an antireflection coating (ARC); FIG. 8 shows a wafer following application of a front-side metal pad; FIG. 9 shows a wafer after wafer bonding, back-grinding, and wet etch back-thinning; FIG. 10 shows a wafer after via hole lithography and wet etch; FIG. 11 shows a wafer after via etch stop (ARC/dielectric) removal; FIG. 12 shows a wafer after passivation layer patterning and hard bake; FIG. 13 shows a wafer after back-side and via-metal isolation lithography; FIG. 14 shows a wafer after back side and TWV-metal deposition; and FIG. 15 shows a completed device after metal lift-off (TWV metal and back-side metal separation).

A semiconductor wafer can first undergo front-side processing (FIGS. 5 to 8). As shown in FIG. 5, a semiconductor wafer can comprise a substrate 505 having a back surface 506 and a front surface 507. A heteroepitaxial layer 504 overlies the front surface 507 of substrate 505. Materials used to form the substrate include, for example, germanium, gallium arsenide, alloys of germanium, and alloys of gallium arsenide. For simplicity, heteroepitaxial layer 504 is shown as a single layer. However, in a multijunction solar cell, it will be understood that multiple epitaxial layers are grown overlying each other, to form a multi-layered heteroepitaxial stack. Materials used to form the heteroepitaxial layer include, for example, alloys of one or more elements from group III and group V on the periodic table, such as indium gallium phosphide, indium phosphide, gallium arsenide, aluminum gallium arsenide, indium gallium arsenide, and dilute nitride compounds.

FIGS. 5 and 6 show cap layer 502 and patterned cap regions 602A that are formed on the front-side of the semiconductor wafer, overlying the heteroepitaxial layer (504 and 604). The cap regions 602A are highly doped semiconductor layers that facilitate electrical connections to the multijunction solar cell. Cap layer 502 is patterned using lithography, to form patterned cap regions 602A. These may be patterned in a disk shape but can also be patterned in any suitable shape and in any suitable geometric configuration, such as shaped in the form of gridlines, busbars, pads and/or any type of conductive element of an electrical device. FIG. 6 shows substrate 605, back substrate surface 606, heteroepitaxial layer 604, and patterned cap regions 602A following post-cap etch.

An ARC (703 in FIG. 7) may be applied over the heteroepitaxial layer 704 and between patterned cap regions 702A. FIG. 7 shows substrate 705, back substrate surface 706, heteroepitaxial layer 704, ARC 703, and patterned cap regions 702A following post-cap etch and deposition of ARC 703 over the portion of the heteroepitaxial layer 704 not covered by patterned cap regions 702A.

A front surface contact (801 in FIG. 8) and narrow metal gridlines (not shown) can be electrically connected to the patterned cap regions 802A. At the end of front-side processing, a semiconductor wafer with an unmodified substrate layer (806) can be obtained, as shown in FIG. 8. FIG. 8 shows substrate 805, back substrate surface 806, heteroepitaxial layer 804 overlying substrate 805, ARC 803 overlying a portion of heteroepitaxial layer 804, patterned cap regions 802A, and front surface contact 801 electrically connected to patterned cap regions 802A.

As shown in FIG. 9, the semiconductor wafer shown in FIG. 8 can be bonded to a cover glass 908 with an optically clear adhesive 907. A cover glass 908 may be a space grade cover glass, which may be made, for example, of borosilicate glass. An optically clear adhesive 907 can be a space-grade adhesive. The back side of the substrate (806 in FIG. 8) can be thinned (909 in FIG. 9) by wet etching, back-grinding, or other methods. A thinned substrate 905 can be between 20 μm and 200 μm, such as from 20 μm to 150 μm, from 20 μm to 100 μm, or from 20 μm to 60 μm, thick post-thinning. Thinned substrates are desirable in some applications, for example, in space solar cells. Thinned substrates are also useful with respect to the subsequent processing to form through-wafer vias. Problems associated with processing thicker substrates can affect geometry and resolution of the vias. Not only are longer etch times required, but there can be issues delivering etchants to the etch front, affecting the rate of etching. The uniformity of the etch at the surface may result in incomplete removal of specific layers. Etched material may be redeposited, and undercutting of layers may also occur. This can affect the surface roughness of the etched via. These effects can lead to additional subsequent processing problems, which in turn can lead to points of failure in the fabricated devices. FIG. 9 shows thinned substrate 905, back substrate surface 909, heteroepitaxial layer 904, ARC 903 overlying portions of the heteroepitaxial layer 904, patterned cap regions (post-cap etch) 902A overlying portions of the heteroepitaxial layer 904, front surface contact 901 overlying a portion of the ARC 903 between the patterned cap regions 902A and electrically connected to patterned cap regions 902A, optically clear adhesive 907, and cover glass 908.

In FIG. 10A, the back substrate surface 1009 is patterned with a photosensitive polymer or any suitable masking material in a desired TWV pattern, aligning the TWV with front surface contact 1001 and patterned cap regions 1002A. Patterned cap regions 1002A can be in the shape of an annular ring that form a perimeter around the ARC-adjacent region of the TWV. Etching TWVs 1010 starts from the back substrate surface 1009 and proceeds 1011 through heteroepitaxial layer 1004, and, as shown in FIG. 10B, stops at the ARC layer 1003A. An etchant mixture for etching the TWV can comprise a volumetric ratio of 10% to 50% hydrochloric acid with a volumetric ratio of 10% to 50% iodic acid in deionized water. The etchant mixture can have a temperature that ranges from 10° C. to 140° C. Etching stops at the ARC 1003 that serves as a selective dielectric etch stop layer for the etching process 1011. Then, the patterned photosensitive polymer/masking material (not shown) and the ARC 1003 that is exposed in the TWV 1010 is removed.

FIG. 10A also shows heteroepitaxial layer 1004, optically clear adhesive 1007, and cover glass 1008. FIG. 10B shows back substrate surface 1009, thinned substrate 1005, heteroepitaxial layer 1004, ARC layers 1003 and 1003A, patterned cap regions 1002A, front surface contact 1001, optical adhesive 1007, and cover glass 1008. Through-wafer via 1010 is wet-etched down to ARC layer 1003A and includes sidewall 1010.

Suitable wet etchant mixtures comprising hydrochloric acid and iodic acid are disclosed, for example, in U.S. Pat. No. 9,263,611, which is incorporated by reference in its entirety. Smooth sidewalls etched with the etchant mixture can comprise traces of iodine. The heteroepitaxial sidewalls can be characterized by a macroscopically smooth surface without significant undercutting and that continuously widens from the substrate to the ARC. In some embodiments, the etchant mixture used can comprise a volumetric ratio of 30% to 35% hydrochloric acid with a volumetric ratio of 14% to 19% iodic acid in deionized water. The etchant mixture can have a temperature within the range from 30° C. to 45° C.

Other wet etching methods and dry etching methods are also known and may be used. A comprehensive list of wet etchants, etch rates and selectivity relationships was published by Clawson, Materials Science and Engineering, 31 (2001) 1-438.

Dry etching, involving the removal of semiconductor material by exposing the material to a plasma of reactive gases in a vacuum chamber may also be used.

FIG. 11 shows the result of the steps described with reference to FIGS. 10A and 10B. FIG. 11 shows the exposed bottom surface 1112 of the front surface contact 1101 after the ARC is removed from TWV hole 1110. The sidewall 1010 of the TWV 1110 is smooth, with an absence of pitting (see also SEM images in FIG. 30). FIG. 11 shows front surface contact 1101, patterned cap regions (post-cap etch) 1102A, ARC (dielectric) 1103, heteroepitaxial layer 1104, substrate 1105, optically clear adhesive 1107, cover glass 1108, back substrate surface 1109 of the wet etched back-thinned substrate 1105, TWV 1110, with sidewall 1010, and exposed bottom surface 1112 of the front surface contact 1201 after TWV etch stop (ARC) removal.

Referring to FIG. 10B, the ARC 1003A at the top of the TWV 1010 (bottom of front surface contact 1001) serves as an etch stop for the wet etch. After the wet etch and via formation the ARC at the top of the TWV can subsequently be removed, for example by dry etching or by wet etching using, for example, hydrofluoric acid, to expose the bottom surface 1112 of front surface contact 1101 (FIG. 11). Residual ARC 1103A can remain between the patterned cap regions 1102A and the TWV 1110.

In certain embodiments, patterned cap regions may not be present and the front surface contact may overly only the ARC 1103. After wet etch and TWV formation, a portion or the entire ARC previously underlying the metal pad may be removed to expose the bottom surface 1112 of the front surface contact 1101. If a portion of the ARC layer is removed there will be a residual ARC 1103A between a portion of the front surface contact 1101 and the heteroepitaxial layer 1104.

As shown in FIG. 12, a passivation layer 1213 is applied over a portion of the thinned back substrate surface 1209 according to a desired pattern to passivate the substrate 1205 from electrical connection to the front surface contact 1201. The passivation layer 1213 also lines the sidewall of the TWV 1210 and provides a conformal coating lining the TWV sidewall and covering a portion of the substrate 1205 adjacent the TWV 1210.

The bottom surface 1212 of the front surface contact 1201 remains exposed after TWV etch stop (ARC) removal and deposition of passivation layer 1213. FIG. 12 shows front surface contact 1201, patterned cap regions (post-cap etch) 1202A, ARC 1203, heteroepitaxial layer 1204, substrate 1205, optically clear adhesive 1207, cover glass 1208, thinned back substrate surface 1209, TWV 1210, exposed bottom surface 1212 of the front surface contact 1201 after TWV etch stop (ARC) removal, and deposition of passivation layer 1213.

In applications where operation over a broad temperature range is required, and where temperature cycling occurs, such as space solar applications, passivation layer 1213 is chosen to minimize the thermo-mechanical stress in the device and is a low stress passivation layer. This requirement is also useful in subsequent processing and packaging steps. Because the semiconductor structure is bonded to a cover glass 1208 with an optically clear adhesive 1207, the temperature ramps for processing and the maximum process temperature that can be used in fabricating the device is limited, which also affects the choice of suitable materials that may be deposited to form the device. To minimize the stress between the different layers making up the device, passivation layer 1213 should have a coefficient of thermal expansion (CTE) close to that of the semiconductor layers (heteroepitaxial layer 1204 and substrate 1205) and should be deposited under processing conditions that the cover glass 1208 and the optical adhesive 1207 can withstand. The CTE for semiconductor materials is typically in the range from about 2.5 ppm/° C. to about 7 ppm/° C.

Common passivation materials used for microelectronics and semiconductors include photoimagable polymers, for example SU-8, AZ 15NXT, and PDMS. Non-photoimagable polymers for passivation are also known and used. These materials are used because they provide good adhesion to the underlying surface onto which they are deposited, and can be deposited using spin coating over broad thickness ranges to produce a conformal coating. However, these passivation materials can have a high CTE, for example, on the order of several tens of ppm/° C. (typically>20 ppm/° C.). Consequently, the large CTE mismatch between a typical passivation material having a high CTE and the CTE of the semiconductor layers can cause a large thermal stress in any subsequent processing or packaging steps, or when a device operates over a large temperature range. Contraction and expansion of the passivation layer can introduce cracks into the semiconductor device.

Dielectric materials such as silicon nitride, silicon dioxide and titanium dioxide are often used as passivation layers. These materials have CTEs close to the CTE of the semiconductor layer. However, producing a conformal coating using these dielectric materials can be more difficult on structures such as TWVs, and in particular on the via sidewall and near the via edge. This can result in imperfect coverage, leading to shorts formed during subsequent metallization steps. Improved adhesion can be achieved using higher temperature deposition, for example, using a high temperature or high energy plasma deposition process. However, this can result in thermal stress and cracking of the wafers. Spin-on glass techniques do not produce the required adhesion for the passivation layer, unless high temperature curing processes are also used.

Alternative passivation materials that have a low CTE include polymeric materials with rigid-rod backbones. These polymeric materials can have CTEs closely matched to those of semiconductor materials, can be processed at low temperatures (when compared to dielectrics) and provide high adhesion to semiconductor surfaces. Examples of suitable polymeric passivation materials include the Polyimide PI-2611 (from HD Microsystems GmbH) and Novastrat® 800 (from NeXolve Corporation).

A low stress passivation layer can have a CTE, for example, less than 10 ppm/° C., less than 8 ppm/° C., less than 6 ppm/° C., or less than 4 ppm/° C. A low stress passivation layer can have a CTE, for example, within a range from 1 ppm/° C. to 10 ppm/° C., from 2 ppm/° C. to 8 ppm/° C., or from 4 ppm/° C. to 6 ppm/° C. A low stress passivation layer can have a CTE that is matched to the average CTE of the semiconductors used in the device such as the average CTE of the heteroepitaxial layers and the substrate, for example, to within ±10%, ±20%, or ±40%. The CTE can represent a CTE over a temperature range, for example, from −200° C. to 150° C., from −150° C. to 100° C., or from −100° C. to 50° C. A low stress passivation layer can have a thickness, for example, from 1 μm to 40 μm, from 5 μm to 30 μm, or from 10 μm to 20 μm.

A low stress passivation layer can have a tensile strength, for example, from 200 MPa to 400 MPa such as from 250 MPa to 350 MPa. A low stress passivation layer can have a Young's modulus, for example, from 7 GPa to 10 GPa such as from 7.5 GPa to 9.5 GPa. A low stress passivation layer can have a tensile elongation, for example, from 80% to 120%, a such as from 90% to 110%. A low stress passivation layer can have a glass transition temperature, for example, from 300° C. to 450° C., such as from 300° C. to 400° C. A low stress passivation layer can have, for example, a coefficient of thermal conductivity from 5E-5 cal/cm×sec×° C. to 50 cal/cm×sec×° C.; a dielectric constant at 1 Hz and 50% RH from 2 to 4 such as from 2.5 to 3.5; a dissipation factor at 1 kHz from 0.0001 to 0.0003; a dielectric breakdown field greater than 1E6 V/cm; a volume resistivity greater than 10E16 Ω cm; and/or a surface resistivity greater than 1E15 Ω. Tensile strength, Young's modulus, and tensile elongation can be determined according to ASTM D882-02 (at 23° C. and for a 0.7-mil thick layer). CTE can be determined using ASTM E831-06, for a 1 mil thick layer.

The passivation layer 1213 can be applied using standard deposition techniques, for example spin coating. In some embodiments, hard baking can be used in a subsequent step. Photolithography and etching can then be used to pattern the passivation layer.

In FIG. 13, TWV metal isolation resist pattern 1314 can be formed with a photosensitive polymer. This patterning can be carried out, for example, by photolithography techniques which may or may not require hard baking, depending on the specific embodiment. The bottom surface 1312 of the front surface contact 1301 remains exposed. FIG. 13 shows front surface contact 1301, patterned cap regions (post-cap etch) 1302A, ARC 1303, heteroepitaxial layer 1304, thinned substrate 1305, optically clear adhesive 1307, coverglass 1308, back surface 1309 of thinned substrate 1305, TWV 1310, exposed bottom surface 1312 of the front surface contact 1301 after TWV etch stop removal, passivation layer 1313, and TWV metal isolation resist pattern 1314.

In FIG. 14, TWV metal 1415 is applied such that the TWV metal 1415 lines the previously exposed bottom of the front surface contact 1401 and lines the sidewall 1416 of TWV 1410, forming an electrical interconnection to the TWV front surface contact 1401. The TWV metal 1415 also lines a portion of the back side of the substrate (1417 and 1419), bounded by the resist 1414 from the previous step (FIG. 13). In some embodiments, these TWV and back side substrate metals (1415, 1416, 1417, and 1419) can be applied in a single deposition step. Sacrificial metal 1418 and metal isolation resist pattern 1414 can then be lifted off to isolate positive and negative electrical contacts (front side and back side electrical contacts), leading to the product shown in FIG. 15. FIG. 14 shows front surface contact 1401, patterned cap regions (post-cap etch) 1402A, ARC 1403, heteroepitaxial layer 1404, optically clear adhesive 1407, and coverglass 1408, overlying the wet etched back-thinned substrate 1405; TWV 1410, passivation layer 1413, back side TWV metal isolation resist pattern 1414, TWV metal 1415 deposited on the bottom of the TWV interconnecting directly to the front surface contact 1401, TWV metal 1416 deposited along the sidewalls of the TWV 1410 isolated from the heteroepitaxial layer 1404 and from the substrate 1405 by the passivation layer 1413, TWV metal 1417 deposited over a portion of passivation layer 1413, back side contact 1419 deposited on the back surface of thinned substrate 1405, and sacrificial metal 1418 on top of the isolation resist 1414.

The example of a completed TWV structure shown in FIG. 15 includes front surface contact 1501, patterned cap regions (post-cap etch) 1502A, ARC 1503, residual ARC 1503A, heteroepitaxial layer 1504, thinned substrate 1505, optically clear adhesive 1507, coverglass 1508, TWV 1510, ARC 1503, TWV metal 1515 deposited on the bottom of the TWV (electrically connecting directly to the top side metal pad 1501), TWV metal 1516 deposited along the sidewall of the TWV 1510 and electrically isolated from the heteroepitaxial layer 1504 and from the thinned substrate 1505 by the passivation layer 1513, TWV metal 1517 deposited on a portion of the back side of the device, and back side contact 1519 electrically connected to substrate 1505.

A TWV can be, for example, from 20 μm to 50 μm deep, or from 10 μm to 200 μm deep, where depth is measured from the bottom of the front surface metal pad 1501 to the bottom surface of the TWV metal 1507 adjacent the TWV 1510. A TWV can have a width, for example, from about 10 μm to 500 μm, from 10 μm to 400 μm, from 100 μm to 400 μm, or from 100 μm to 250 μm, where width is measured from the interface between the heteroepitaxial layer 1504 and the passivation layer 1513 to the corresponding opposite interface. A TWV can be characterized, for example, by an aspect ratio from 0.5 to 1.5 from 0.8 to 1.2, or from 0.9 to 1.1, where the aspect ratio refers to the ratio of the depth to width.

Referring to FIG. 15, depending on the width at the top of the TWV structure (at the bottom surface of the front surface metal pad 1501 between the patterned cap regions 1502A, there can be a residual ARC 1503A or section between a portion of the front side metal 1501 and the heteroepitaxial layer 1504. The residual ARC layer 1503A can overlie a portion of the heteroepitaxial layer between the patterned cap region 1502A and the passivation layer 1513 on the sidewall of the TWV. If the width of the top of the TWV is large, then there may not be a residual ARC layer in the top of the TWV within the patterned cap region.

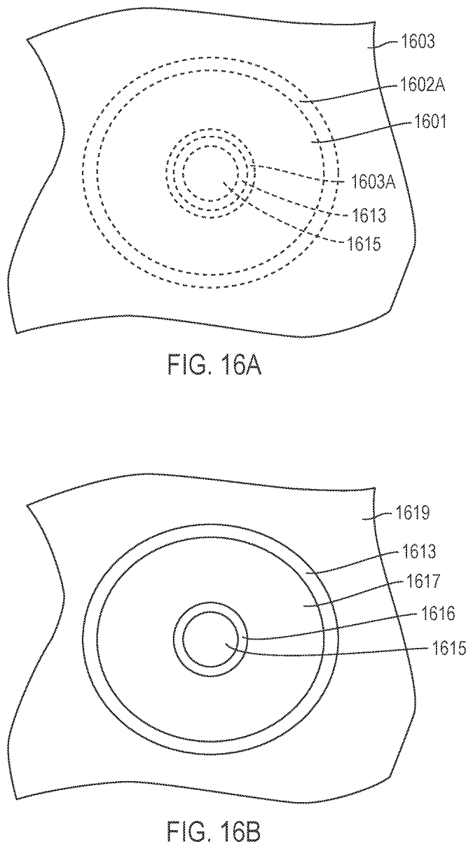

FIG. 16A and FIG. 16B each show a cross-section of a completed device as shown in FIG. 15 viewed from the top of the semiconductor wafer and from the bottom of the semiconductor wafer, respectively. This device was manufactured using the processes illustrated in FIGS. 5 to 15. FIG. 16A and FIG. 16B represent an example of a particular embodiment and do not limit the present disclosure. Modifications in the processes and the resulting devices by one skilled in the art may result in final products with variations. Possible variations include device structure, shape, materials and dimensions. For example, although the patterned cap regions 1602A and front surface contact 1601 are shown to be annular, they are not limited to this shape and represent only an embodiment of the present disclosure. Other shapes that may be used include, for example, squares and rectangles. In the example of a device that is manufactured by processes shown in FIGS. 5 to 15, a front surface metal pad lies directly over the TWV. From the top side of the device (FIG. 16A), the following components of the device are shown: front surface contact 1601, patterned cap regions 1602A, and ARC 1603. The TWV is directly beneath front surface contact 1601 and within the annular pattered cap regions 1602A, and includes residual ARC 1603A, passivation layer 1613, and TWV metal 1615 that interconnects directly to the bottom of front surface contact 1601. From the bottom side (FIG. 16B), the following components of the device are shown: back surface contact 1619, passivation layer 1613, TWV metal 1615 electrically connected to the bottom surface of front surface contact (not shown), TWV metal 1616 along the sidewall of the TWV isolated from the heteroepitaxial layer and from the substrate by the passivation layer, and TWV metal 1617 deposited on a portion of the back surface of the device adjacent the TWV. These are examples of a particular embodiment and do not limit the scope of the disclosure. Modifications in the method and the device disclosed may result in final products with variations. The final product fabricated by methods in the disclosure will have smooth sidewalls instead of lateral undercutting and pitting of the semiconductor wafer as shown, for example, in FIGS. 28 and 29.

This is an advantageous improvement over prior art, resulting in improved fabrication reliability and yield of devices that comprise a heteroepitaxial layer. Bonding the coverglass to the front surface of the device before fabrication of the TWV provides a carrier for subsequent processing. Most importantly the thick substrate used during epitaxial growth can be thinned using one or more methods to provide a thin substrate. The thinned substrate facilitates the formation of high quality TWVs using wet etching and can significantly reduce the overall weight of the multijunction photovoltaic cell.

Methods of forming a semiconductor device can comprise the steps of: providing a semiconductor wafer, wherein the semiconductor wafer comprises: a substrate region comprising a front side and a back side; a heteroepitaxial layer overlying the front side of the substrate region, wherein, the heteroepitaxial layer comprises a first subcell and at least one additional subcell overlying the first subcell; and at least one of the first subcell or the at least one additional subcell comprises an alloy comprising one or more elements from group III of the periodic table, N, As, and an element selected from Sb, Bi and a combination thereof; a plurality of patterned cap regions overlying the heteroepitaxial layer; an anti-reflective coating overlying the heteroepitaxial layer; and a corresponding metal region overlying each of the plurality of patterned cap regions; bonding a coverglass to the front side of the semiconductor wafer with an optically clear adhesive; removing a desired amount from the semiconductor wafer by a thinning of the substrate region from the back side of the semiconductor wafer; patterning the back side of the semiconductor wafer with a back etch through-wafer via pattern; etching from the back side of the semiconductor wafer a plurality of through-wafer vias using a single wet etchant mixture, wherein each of the plurality of through-wafer vias extends from the back side of the semiconductor wafer to the anti-reflective coating overlying the heteroepitaxial layer; removing the anti-reflective coating to expose a bottom side of the corresponding metal region with a subsequent wet etching method, wherein the subsequent wet etching method is specific for the removal of the anti-reflective coating; depositing a passivation layer on the through-wafer via walls with standard deposition techniques; depositing a resist pattern on the back side of the semiconductor wafer for back side metal isolation, wherein the resist pattern underlies the passivation layer; depositing a metal on the back side of the semiconductor wafer and on the through-wafer via; and removing the resist pattern and a sacrificial metal.

Semiconductor devices can comprise a heteroepitaxial layer, further comprising an alloy comprising one or more elements from group III of the periodic table, N, As, and an element selected from Sb, Bi and a combination thereof; and a plurality of through-wafer vias characterized by the absence of pitting on smooth sidewall surfaces formed by a method provided by the present disclosure.

Through-wafer via structures can comprise a substrate comprising a back side and a front side; a heteroepitaxial layer overlying the front side of the substrate; an antireflection coating overlying a first portion of the heteroepitaxial layer; a patterned cap region overlying a second portion of the heteroepitaxial layer; a front surface contact overlying and electrically connected to the patterned cap region, wherein the front surface contact comprises a bottom surface; and a through-wafer via extending from the back side of the substrate to the front surface contact, wherein the through-wafer via comprises a sidewall; a low stress passivation layer overlying a portion of the back side of the substrate and the sidewall of the through-wafer via; and a metal layer overlying the low stress passivation layer and the bottom surface of the front surface contact within the through-wafer via.

SMCCs provided by the present disclosure facilitate low-cost, low-complexity, high-speed fabrication of solar arrays with low mass and high reliability. This is accomplished by eliminating welding processes and bulky interconnects, reducing the thickness and cost of the backside metal, reducing the overall mass of the photovoltaic device by using a thin substrate, integrating the coverglass during wafer processing, increasing solar array area utilization with the interconnections and bypass diodes integrated with interconnection substrates such as PWBs/PCBs, and increasing wafer utilization with small cells.

SMCC photovoltaic cells can be used with well-known, highly automated surface mount equipment, SMCC cells can be mounted directly to a PWB, PCB, or other interconnection substrate, which includes the interconnects between subcells. By eliminating welding interconnection strings between subcells, it becomes cost-effective to use smaller photovoltaic cells. Smaller SMCC photovoltaic cells facilitate more efficient and economical use of solar array surface area. More effective utilization of solar array area results in higher power, lower weight, and lower cost per solar cell array area.

SMCC devices provided by the present disclosure can have a front surface area, for example, of 5 cm² or less, 4 cm² or less, 3 cm² or less, 2 cm² or less, or 1 cm² or less. For example, a SMCC device provided by the present disclosure can have a front surface area from 0.5 cm²to 5 cm², from 0.5 cm²to 4 cm², from 0.5 cm²to 3 cm², from 0.5 cm²to 2 cm², or from 0.5 cm² to 1 cm². SMCC photovoltaic cells can also have other dimensions.

SMCC devices provided by the present disclosure, such as three junction SMCC devices, can have a unit mass per area less than 0.10 g/cm², a unit mass per area, for example, less than 0.09 g/cm², less than 0.08 g/cm², less than 0.07 g/cm², or less than 0.06 g/cm². SMCC devices provided by the present disclosure, such as three junction SMCC devices, can have a unit mass per area, for example, from 0.05 g/cm² to 0.10 g/cm², from 0.06 g/cm² to 0.09 g/cm², or from 0.06 g/cm² to 0.08 g/cm².

For assembly of an SMCC device to an interconnection substrate, solder balls or solder paste can be applied to the contact pads. The SMCC devices with applied solder can then then assembled onto corresponding reciprocal contact pads on a printed circuit board and the solder reflowed to interconnect the SMCC to the printed circuit board.

### EXAMPLES

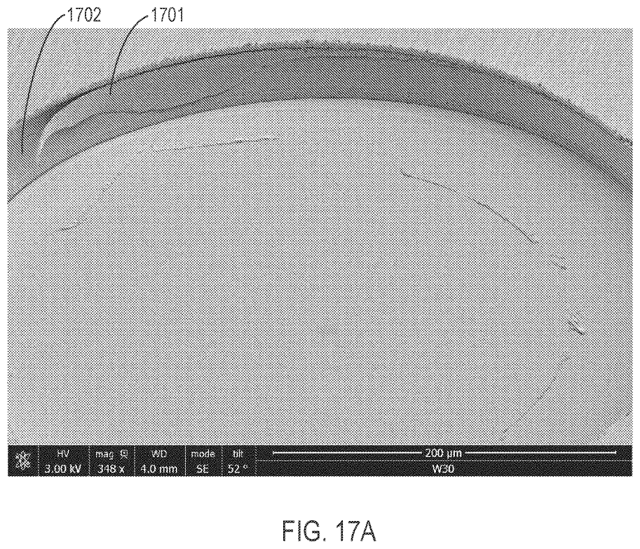

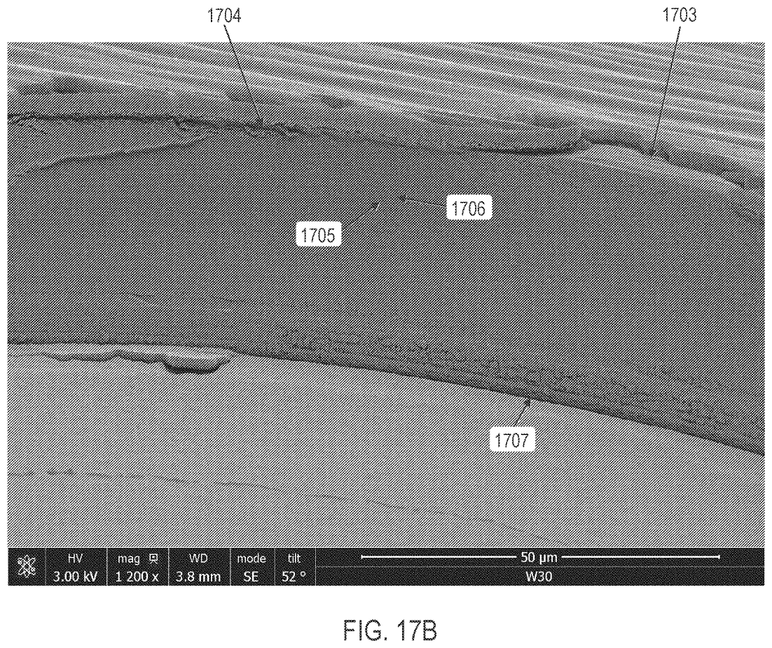

The choice of passivation layer is important to produce reliable devices that can withstand thermal cycling and associated thermo-mechanical stress. FIGS. 17A and 17B show cross-sectional views of a dielectric passivation layer deposited onto a sidewall of a TWV. The passivation layer comprises TiO₂/SiO₂, deposited using electron-beam evaporation. FIG. 17A shows that there is poor adhesion to the TWV sidewall that leads to incomplete passivation layer coverage. During subsequent processing steps, metal can become deposited directly on the semiconductor, causing a short circuit. This is evident in FIG. 17A, which shows a region of the passivation layer peeling 1701 peeling away from the sidewall, and metal deposited directly on the semiconductor 1702. FIG. 17B shows that the TiO₂/SiO₂ passivation layer is present of the top of the substrate 1704, and therefore via metal that covers this surface is isolated from the semiconductor by the passivation layer. However, toward the edge of the via, the passivation layer has peeled off 1703, resulting in metal being deposited directly on the semiconductor. Again, poor adhesion of the passivation layer causes delamination from sidewalls 1705, and metal can coat the semiconductor layers directly, causing a short circuit to occur 1706. Furthermore, there can be gaps 1707 introduced in the metal coverage.

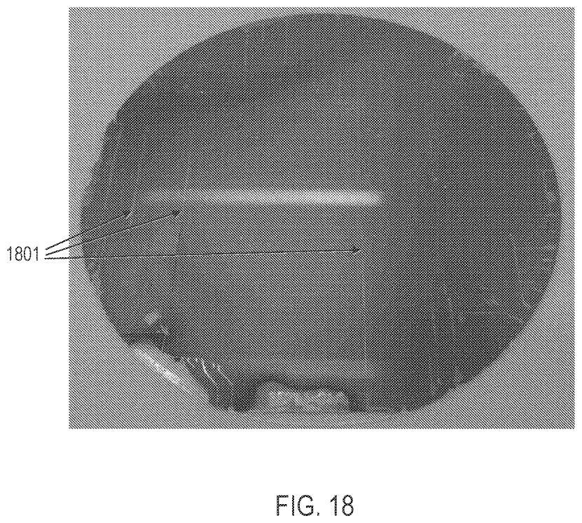

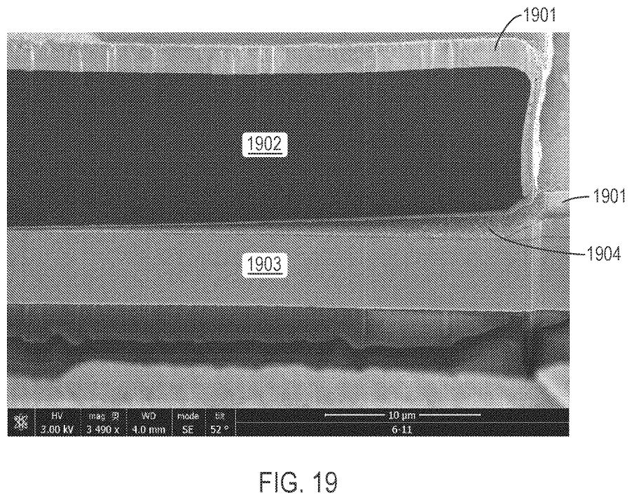

FIG. 18 shows a photograph of a wafer with dielectric passivation, where a higher deposition temperature was used for improved adhesion. Wafer cracking 1801 is clearly observed, as indicated by the arrows.

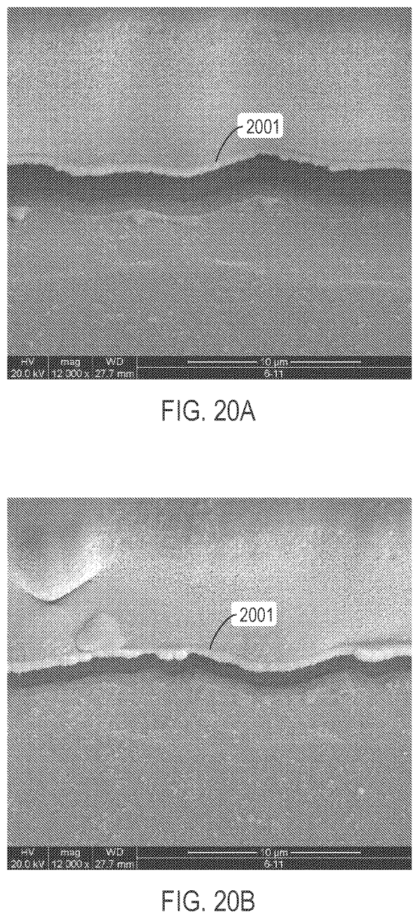

Alternatively, photoresist passivation layers can be used. However, the high CTE results in passivation delamination and metal cracking occurring at the weakest interface in the structure. FIG. 19 and FIG. 20 show cross-sectional views of TWVs with a photoresist passivation layer. The photoresist in this example is AZ® 15NXT (from MicroChemicals GmbH), with a thickness of about 10 μm. FIG. 19 shows delamination or lifting 1904 of the passivation layer 1902 from the via metal 1901 at the bottom of the via, at the front-side metal 1903. This is caused by passivation shrinkage and lifting, and the crack causes an open circuit connection to occur as the via metal is no longer a continuous layer in contact with the front surface contact. Metal cracking 2001 is also shown in FIGS. 20A and 20B, for two different TWVs having photoresist passivation layers.

In certain embodiments according to the present invention, a passivation layer can be formed using a low-stress polymer material and is referred to as a low stress passivation layer. In one example, the low-stress polymer is polyimide material PI-2611 (from HD Microsystems). This material has a rigid-rod backbone that results in a low CTE of 3 ppm/° C. Polymers having rigid-rod backbones generally have the lowest CTE values in the approximate range of the CTE for semiconductor materials (between about 2.5 ppm/° C. and 7 ppm/° C.). Another example of such a polyimide material, is Novastrat® 800 (from NeXolve Corporation) which has a CTE of 6 ppm/° C. In some embodiments, adhesion promoters can be used to enhance adhesion between the polyimide and the underlying layers. For PI-2611, the manufacturer recommends using aminosilane-based adhesion promoters such as VM-651 or VM-652 (from HD Microsystems GmbH). However, other suitable adhesion promoters are known and include, for example, to HMDS (hexamethyldislazane), diphenylsilanediol-derivatives (AR 300-80), and cationic priming agents, for example SurPass. In some embodiments, the thickness of the low stress passivation layer can be between 1 μm and 40 μm. In some embodiments, the thickness of the low stress passivation layer can be between 5 μm and 20 μm. In some embodiments, the thickness of the low stress passivation layer can be between 7.5 μm and 12.5 μm. In some embodiments, the low stress passivation layer may be formed using at least one spin-coating step.

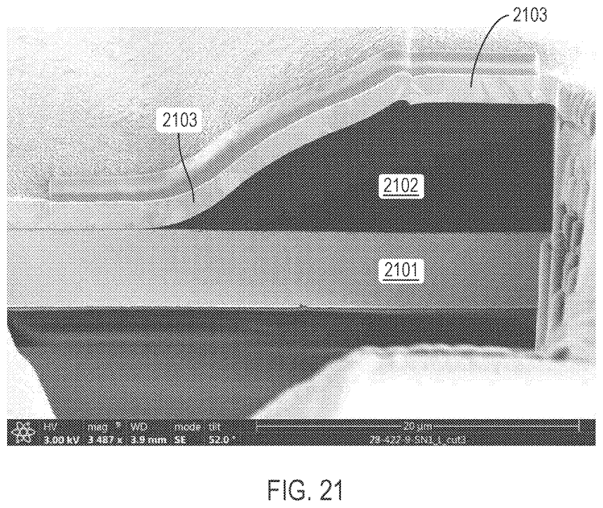

FIG. 21 show cross-sectional views for a PI-2611 passivation layer within a TWV. The polyimide passivation layer 2102 has a thickness of about 10 μm, adheres well to the front surface metal pad 2101, and no delamination is observed after curing at 250° C. The TWV metal layer 2103 that is deposited after the polyimide passivation layer 2102 is thermally cured forms a continuous conformal layer and is in contact with the frontside metal, with no metal cracking.

For integration with a PCB, solder balls or solder paste can be applied to the contact pads, or solder pads interconnected with the contact pads. For example, it may be applied to the contact pads formed by back surface contact 1519 and TWV metal 1517 (FIG. 15), corresponding to back surface contact 407 and front surface pad 408 (FIG. 4), or it may be applied to back surface mount solder pads (308) and front side surface mount solder pads (312) (FIG. 3). Solder pads may be formed using standard lithography and metal deposition steps.

A typical PCB laminate, FR-4, has a CTE of 14 ppm/° C. to 17 ppm/° C. Lower CTE PCB materials are known and may be used. For example, FR-4 with a metal core (for example, copper-Invar-copper or copper-molybdenum-copper), or that incorporates an aramid, Kevlar® or Thermount® laminate can have a CTE less than 12 ppm/° C. Integration of SMCC devices via solder bump to the PCB can also introduce thermal stresses. The low-stress polyimide passivation layer helps to buffer the SMCC device from these stresses, mitigating effects such as delamination, as previously described and thereby creating a more reliable integrated component.

### ASPECTS OF THE INVENTION

Aspect 1. A through-wafer via structure, comprising: a substrate having a front substrate surface and a back substrate surface, wherein the substrate has a thickness from 20 μm to 200 μm; a plurality of heteroepitaxial layers overlying the front substrate surface; a front surface contact overlying a portion of and electrically connected to the plurality of heteroepitaxial layers; an optical adhesive overlying the front surface contact and the plurality of heteroepitaxial layers; a coverglass overlying the optical adhesive; a back surface solder pad underlying a portion of and electrically connected to the back substrate surface; a front surface solder pad underlying and insulated from the back substrate surface; and a through-wafer-via interconnecting the front surface solder pad and the front surface contact, wherein the through-wafer via comprises a sidewall and a low stress passivation layer lining the sidewall.

Aspect 2. The through-wafer via structure of aspect 1, wherein the low stress passivation layer comprises a polyimide.

Aspect 3. The through-wafer via structure of any one of aspects 1 to 2, wherein the low stress passivation layer has a coefficient of thermal expansion from 1 ppm/° C. to 10 ppm/° C., over a temperature range from −100 ° C. to 50 ° C.

Aspect 4. The through-wafer via structure of any one of aspects 1 to 3, wherein the low stress passivation layer has a thermal expansion coefficient that matches an average thermal expansion coefficient of the substrate and of the plurality of heteroepitaxial layers within ±40%.

Aspect 5. The through-wafer via structure of any one of aspects 1 to 4, wherein the low stress passivation layer has a thickness from 1 μm to 40 μm.

Aspect 6. The through-wafer via structure of any one of aspects 1 to 5, wherein the sidewall is smooth.

Aspect 7. The through-wafer via structure of any one of aspects 1 to 6, wherein the back substrate surface is free from pitting.

Aspect 8. A semiconductor device comprising the through-wafer via structure of any one of aspects 1 to 7.

Aspect 9. A multijunction photovoltaic cell comprising the through-wafer via structure of any one of aspects 1 to 7.

Aspect 10. A photovoltaic module comprising a plurality of the multijunction photovoltaic cells of aspect 9.

Aspect 11. The photovoltaic module of aspect 10, comprising an interconnection substrate comprising a front interconnection substrate surface and a back interconnection substrate surface; wherein the plurality of surface mount multijunction photovoltaic cells are mounted to the interconnection substrate.

Aspect 12. The photovoltaic module of aspect 11, wherein the interconnection substrate comprises: interconnects between each of the plurality of surface mount multijunction photovoltaic cells; and a plurality of bypass diodes, wherein each of the plurality of bypass diodes is interconnected to one or more of the plurality of surface mount multijunction photovoltaic cells, and wherein each of the plurality of bypass diodes is mounted to the interconnection substrate.

Aspect 13. The photovoltaic module of any one of aspects 10 to 12, wherein, the photovoltaic module comprises a front surface area; and the plurality of multijunction photovoltaic cells cover at least 70% of the front surface area.

Aspect 14. A power system comprising the photovoltaic module of any one of aspects 10 to 13.

Aspect 15. A method of fabricating a through-wafer via structure, comprising: (a) providing a semiconductor wafer, wherein the semiconductor wafer comprises: a substrate comprising a front substrate surface and a back substrate surface; a plurality of heteroepitaxial layers overlying the front substrate surface; a front surface contact overlying and electrically connected to a portion of the plurality of heteroepitaxial layers; an optical adhesive overlying the front surface contact and the plurality of heteroepitaxial layers; and a coverglass overlying the optical adhesive layer; (b) thinning the substrate to a thickness from 20 μm to 150 μm; (c) forming a through-wafer via interconnecting the front surface contact, wherein the through-wafer-via comprises a sidewall and a low stress passivation layer lining the sidewall; and (d) forming a front contact pad interconnecting the through-wafer via and to the front surface contact.

Aspect 16. The method of aspect 15, wherein the low stress passivation layer comprises a polyimide.

Aspect 17. The method of any one of aspects 15 to 16, wherein the low stress passivation layer has a coefficient of thermal expansion from 1 ppm/° C. to 10 ppm/° C., over a temperature range from −100° C. to 50° C.

Aspect 18. The method of any one of aspects 15 to 17, wherein the low stress passivation layer has a thermal expansion coefficient that matches an average thermal expansion coefficient of the substrate and of the plurality of heteroepitaxial layers within ±40%.

Aspect 19. The method of any one of aspects 15 to 18, wherein the low stress passivation layer has a thickness from 1 μm to 40 μm.

Aspect 20. The method of any one of aspects 15 to 19, wherein the sidewall is smooth.

Aspect 21. The method of any one of aspects 15 to 20, wherein the back substrate surface is free from pitting.

Finally, it should be noted that there are alternative ways of implementing the embodiments disclosed herein. Accordingly, the present embodiments are to be considered as illustrative and not restrictive. Furthermore, the claims are not to be limited to the details given herein, and are entitled their full scope and equivalents thereof.

1. A through-wafer via structure, comprising:
a substrate having a front substrate surface and a back substrate surface, wherein the substrate has a thickness from 20 μm to 200 μm;
a plurality of heteroepitaxial layers overlying the front substrate surface;
a front surface contact overlying a portion of and electrically connected to the plurality of heteroepitaxial layers;
an optical adhesive overlying the front surface contact and the plurality of heteroepitaxial layers;
a coverglass overlying the optical adhesive;
a back surface solder pad underlying a portion of and electrically connected to the back substrate surface;
a front surface solder pad underlying and insulated from the back substrate surface; and
a through-wafer-via interconnecting the front surface solder pad and the front surface contact, wherein the through-wafer via comprises a sidewall and a low stress passivation layer lining the sidewall.

2. The through-wafer via structure of claim 1, wherein the low stress passivation layer comprises a polyimide.

3. The through-wafer via structure of claim 1, wherein the low stress passivation layer has a coefficient of thermal expansion from 1 ppm/° C. to 10 ppm/° C., over a temperature range from −100° C. to 50° C.

4. The through-wafer via structure of claim 1, wherein the low stress passivation layer has a thermal expansion coefficient that matches an average thermal expansion coefficient of the substrate and of the plurality of heteroepitaxial layers within ±40%.

5. The through-wafer via structure of claim 1, wherein the low stress passivation layer has a thickness from 1μm to 40 μm.

6. The through-wafer via structure of claim 1, wherein the sidewall is smooth.

7. The through-wafer via structure of claim 1, wherein the back substrate surface is free from pitting.

8. A semiconductor device comprising the through-wafer via structure of claim 1.

9. A multijunction photovoltaic cell comprising the through-wafer via structure of claim 1.

10. A photovoltaic module comprising a plurality of the multijunction photovoltaic cells of claim 9.

11. The photovoltaic module of claim 10, comprising an interconnection substrate; wherein the plurality of the multijunction photovoltaic cells is mounted to the interconnection substrate.

12. The photovoltaic module of claim 11, wherein the interconnection substrate comprises:
interconnects between each of the plurality of the multijunction photovoltaic cells; and
a plurality of bypass diodes, wherein each of the plurality of bypass diodes is interconnected to one or more of the plurality of the multijunction photovoltaic cells, and
wherein each of the plurality of bypass diodes is mounted to the interconnection substrate.

13. The photovoltaic module of claim 10, wherein,
the photovoltaic module comprises a front surface area; and
the plurality of the multijunction photovoltaic cells cover at least 70% of the front surface area.

14. A power system comprising the photovoltaic module of claim 10.

15. A method of fabricating a through-wafer via structure, comprising:
(a) providing a semiconductor wafer, wherein the semiconductor wafer comprises:
a substrate comprising a front substrate surface and a back substrate surface;
a plurality of heteroepitaxial layers overlying the front substrate surface;
a front surface contact overlying and electrically connected to a portion of the plurality of heteroepitaxial layers;
an optical adhesive overlying the front surface contact and the plurality of heteroepitaxial layers; and
a coverglass overlying the optical adhesive layer;
(b) thinning the substrate to a thickness from 20 μm to 150 μm;
(c) forming a through-wafer via interconnecting the front surface contact, wherein the through-wafer-via comprises a sidewall and a low stress passivation layer lining the sidewall; and
(d) forming a front contact pad interconnecting the through-wafer via to the front surface contact.

16. The method of claim 15, wherein the low stress passivation layer comprises a polyimide.

17. The method of claim 15, wherein the low stress passivation layer has a coefficient of thermal expansion from 1 ppm/° C. to 10 ppm/° C., over a temperature range from −100° C. to 50° C.

18. The method of claim 15, wherein the low stress passivation layer has a thermal expansion coefficient that matches an average thermal expansion coefficient of the substrate and of the plurality of heteroepitaxial layers within ±40%.

19. The method of claim 15, wherein the low stress passivation layer has a thickness from 1 μm to 40 μm.

20. The method of claim 15, wherein the sidewall is smooth.

21. The method of claim 15, wherein the back substrate surface is free from pitting.
